(19) United States
(12) Patent Application Publication
(10) Pub. No.: US 2026/0059673 A1
(43) Pub. Date: Feb. 26, 2026

(54) DOOR FRAME ASSEMBLY WITH INTEGRATED VENTILATION, DISPLAY ASSEMBLIES, DISPLAY UNITS, SYSTEMS, AND METHODS INCORPORATING THE SAME

(71) Applicant: Manufacturing Resources International, Inc., Alpharetta, GA (US)

(72) Inventors: William Dunn, Alpharetta, GA (US); Mike Brown, Cumming, GA (US); Andrew Raygoza, Atlanta, GA (US); Tim Hubbard, Alpharetta, GA (US); Fletcher Bean, Alpharetta, GA (US); Matt Dosch, Alpharetta, GA (US)

(21) Appl. No.: 19/377,151

(22) Filed: Nov. 3, 2025

Related U.S. Application Data
(63) Continuation-in-part of application No. 18/973,914, filed on Dec. 9, 2024, now Pat. No. 12,493,206.
(63) Continuation-in-part of application No. PCT/US2024/048764, filed on Sep. 27, 2024.
(60) Provisional application No. 63/541,567, filed on Sep. 29, 2023.
(60) Provisional application No. 63/625,442, filed on Jan. 26, 2024.

(51) Int. Cl. H05K 5/02; G09F 9/33; G09F 9/35; H05K 5/03

(52) U.S. Cl. CPC H05K 5/0213; H05K 5/03; G09F 9/33; G09F 9/35

(57) ABSTRACT

A door frame for a display assembly of a display unit is disclosed, along with related display assemblies, units, systems, and methods. The door frame includes a body which is at least substantially planar. At least one vent is provided at the body. A cover is installable to a lip of the door frame which extends at least substantially perpendicular to the body and from an end thereof. The door frame subassembly is replaceable, such as to repair damaged covers offsite. The door frame may be formed by extrusion and bending.

### CROSS-REFERENCE TO RELATED APPLICATIONS

This application is a continuation-in-part of U.S. application Ser. No. 18/973,914 filed Dec. 9, 2024; this application is also a bypass continuation-in-part of PCT/US2024/048764 filed Sep. 27, 2024, which claims the benefit of U.S. Provisional Application Ser. No. 63/541,567 filed Sep. 29, 2023 and U.S. Provisional Application Ser. No. 63/625,442 filed Jan. 26, 2024; the disclosures of each of the foregoing are hereby incorporated by reference as if fully restated herein.

### TECHNICAL FIELD

Exemplary embodiments relate generally to door frame assemblies with integrated ventilation, such as for display assemblies, such as for display units, such as which permit efficient replacement and repair, systems, and methods related to the same.

### BACKGROUND AND SUMMARY OF THE INVENTION

Digital out of home (“DOOH”) advertising is an increasingly popular field. These DOOH assemblies are sometimes used to show advertising and/or public announcements. Being typically installed in public places with relatively high population densities, these display assemblies have, unfortunately, sometimes been the target of vandals. Despite attempts to make the display assemblies vandalism resistant, vandals sometime succeed in scratching or breaking parts of the display assemblies, such as the covers. Additionally, being installed outside at a variety of locations, these display assemblies are often exposed to harsh and varied conditions. Despite attempts to make the display assemblies resistant to weather and other external conditions, sometimes parts of the display assemblies, such as the covers, become damaged by other external events or conditions (e.g., weather, vehicle collisions). Regardless of the cause, the covers of such display assembles sometimes become damaged and/or otherwise need replaced. Replacing the cover can be resource intensive efforts and may include blocking off areas around the display assemblies, transporting a new cover to the display assemblies, removing the old cover, and installing the new cover. Sometimes, this effort requires replacing a whole electronic display or subassembly thereof.

What is needed is a display assembly with a replaceable cover. Display assemblies with replaceable covers are disclosed, along with related subassemblies, systems, and methods. A door subassembly includes a door frame. Clips are removably attachable to the door frame, such as by way of threaded fasteners and nuts. The door frame may be rectangular in shape. The clips may be provided on a one-to-one basis with sides of the door frame. The clips may collectively surround an outer perimeter of the door frame. For example, one clip may be provided for each of four sides of the rectangular shaped door frame. Vents may be provided in the clips to align with vents of the door frame, such as at top and bottom clips and side of the door frame. Each clip may include a fascia and a stud. The stud may be adhered, welded, bonded, or otherwise permanently attached to an interior surface of the fascia. The stud may add strength and/or rigidity to the clip. The fascia may include a lip which extends over at least part of a front surface of the cover. The fasteners may extend from a space between the stud and the fascia through an aperture of the stud and an aligned aperture in the door frame where the nut is installed, thereby connecting the clips to the door frame.

The door frame may include a ledge for receiving a portion of a rear surface of the cover. The ledge of the door frame and lip of clips may sandwich the cover, thereby securing the cover, at least in part.

Where a cover of a display assembly (sometimes also referred to herein as a “unit”) is damaged or otherwise in need of replacement, a display subassembly of the unit, which may include the cover subassembly, may be moved away from a structural framework of the unit to which the display subassembly is movably connected (e.g., hinged). The nuts may be backed off the threaded fasteners so that the clips and cover (or what remains thereof) may be removed.

A replacement cover may be installed locally, such as by removing the clips and existing cover or remainder thereof. However, more preferably (but optionally), a replacement cover subassembly (e.g., with at least the new replacement cover as well as a replacement door frame and/or clips) is installed, either with a new set of nuts and/or fasteners or reusing some or all of the nuts and/or fasteners. Where the replacement cover subassembly is installed, the removed cover subassembly may be transported offsite where a new cover is installed. This allows refurbishment of the cover subassembly (e.g., at least the door frame and/or clips), such as for subsequent reuse. This may minimize time needed onsite. This may also permit a replacement cover subassembly essentially be on standby to service a relatively large number of units. The clips may, alternatively or additionally, enhance strength.

In other exemplary embodiments, a unitary door frame may be provided, such as part of a replaceable door frame subassembly. The door frame may include an at least substantially planar body and a lip extending at least substantially perpendicular from an end of the body, such as with a rounded connection therebetween. The door frame may be formed by extrusion and subsequent bending, such as into a cuboid shape.

An interior component may be provided, which may include a body and a lip extending therefrom. The interior component may include an at least substantially planar body and a lip extending at least substantially perpendicular from an end of the body, such as with a rounded connection therebetween. The interior component, and particularly the body and lip thereof, may at least substantially align with a door frame, and particularly the body and the lip portion thereof, respectively. For example, the body of the door frame may extend at least substantially parallel with the body of the interior component, and the lip of the door frame may extend at least substantially parallel with the lip of the interior component.

The interior component may be connected to the door frame via fasteners, such as nuts or bolts inserted through holes in the body of the interior component and into channels formed on an interior facing side of the body of the door frame. For example, without limitation, heads of the fasteners may be secured within the channels of the door frame and threaded portions of the fasteners may be extended through holes in the body of the interior component, and a nut may be tightened against the interior component to secure the interior component and the door frame to one another.

An interior surface of the lip of the door frame may be sufficiently spaced from an outward facing surface of the lip of the interior component to accommodate the cover, which may include multiple layers joined by an optically clear adhesive.

In exemplary embodiments, without limitation, a material is interposed between the interior surface of the cover and the outward facing surface of the lip of the interior component. A gasket may be provided which extends to at least one of the channels of the door frame and between the interior facing surface of the lip of the door frame and the outward facing surface of the cover. The material and/or gasket preferably comprises one or more rubbers or silicones, though other types and kinds of material may be utilized. The material and/or gasket may assist with sealing, reduce fiction, provide adhesion, combinations thereof, or the like. The gasket preferably comprises one or more end portions which engage portions of the door frame, and preferably those portions forming at least one of the channels. The material and/or gasket may extend along at least some of an outer perimeter surface of the cover.

Securing the interior component to the door frame with the cover in place may result in the cover being secured by frictional engagement. In this way a door frame subassembly, which may include at least the door frame, interior component, and cover, may be removed from the display assembly and/or the unit, such as to replace a broken or damaged cover, such as on site or at an offsite location, such as by replacing the door frame subassembly with another one at the time of removal. This may allow for more efficient repair and replacement.

Vents may be provided at the door frame, such as at upper and lower portions thereof, preferably at portions of the body of the door frame corresponding to the same. This may allow for a larger area for airflow ingestion and exhaustion when the one or more display assemblies are installed as part of the unit, particularly in combination with the vents forming part of the structural framework. Preferably, the vents in the door frame are aligned with the vents in the structural framework. This may allow for more efficient airflow and/or thermal management, such as by reducing backpressure, reducing air velocity (allowing longer dwell times for thermal transfer), and/or reducing noise.

The lip of the door frame assembly may aid with securing the cover, such as from popping out due to internal pressure forces generating during use and/or ambient condition exposure. For example, without limitation, solar heating of air behind the cover and/or airflow changes to such air can cause significant pressure increases against the cover, which, particularly when repeated over the years, can tend to lead to undesirable conditions (e.g., leaking, breakage).

The body of the interior component extends interior to the vents of the door frame, thereby acting as a sort of umbrella. This may prevent moisture, such as from ambient rain, from traveling further into the unit, thereby reducing moisture exposure to sensitive electronics within the units, such as by preventing direct contact and leakage through capillary action or otherwise.

Further features and advantages of the systems and methods disclosed herein, as well as the structure and operation of various aspects of the present disclosure, are described in detail below with reference to the accompanying figures.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical, similar, or equivalent features, and wherein:

FIG. 1 is an exploded, perspective view of an exemplary replaceable cover subassembly;

FIG. 2 is a detailed, exploded perspective view of the replaceable cover subassembly of detail A of FIG. 1;

FIG. 3 is a detailed, perspective view of an exemplary display subassembly with the replaceable cover subassembly of FIGS. 1-2;

FIG. 4 is a perspective view of an exemplary display assembly with the replaceable cover subassembly of FIGS. 1-2 and/or display subassembly of FIG. 3;

FIG. 5 is a bottom perspective view of another exemplary display assembly with the replaceable cover subassembly of FIGS. 1-2 with the display subassembly, such as of FIG. 3, in an open position;

FIG. 6 is the bottom perspective view of the display assembly of FIG. 5 with the door subassembly removed;

FIG. 7 is a flow chart with an exemplary method of replacing the replaceable cover subassembly of FIGS. 1-2 at the display subassembly of FIG. 3 and/or the display assembly of FIGS. 4-6;

FIG. 8 is a flow chart with another exemplary method of replacing the replaceable cover subassembly of FIGS. 1-2 at the display subassembly of FIG. 3 and/or the display assembly of FIGS. 4-6;

FIG. 9 is a perspective view of an upper portion of another exemplary embodiment of the display assembly of FIGS. 1-6;

FIG. 10 is a perspective view of a lower portion of the display assembly of FIG. 9;

FIG. 11 is a perspective sectional view of the upper portion of the display assembly of FIG. 9;

FIG. 12 is a perspective view of a door frame subassembly and cover subassembly of the display assembly of FIGS. 9-11;

FIG. 13 is a perspective sectional view of a portion of the door frame subassembly and cover subassembly of FIG. 12; and

FIG. 14 is a perspective view of another portion of the door frame subassembly and the cover subassembly of FIG. 12.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

Embodiments of the invention are described herein with reference to illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

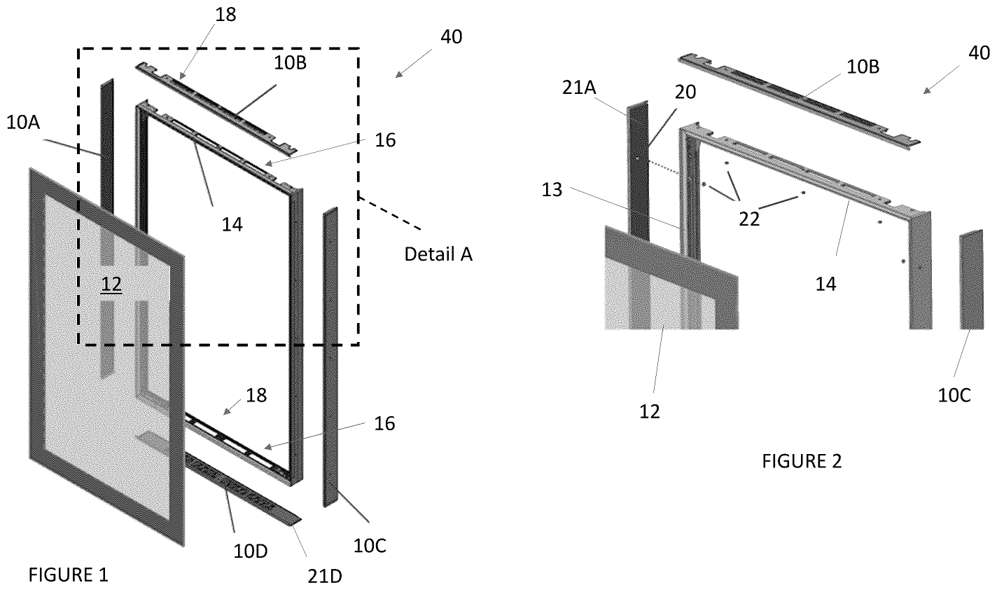

FIG. 1 and FIG. 2 illustrate an exemplary cover subassembly 40.

The cover subassembly 40 may comprise a door frame 14. The door frame 14 may be configured to accommodate a cover 12. For example, without limitation, the door frame 14 may be sized and/or shaped to accommodate the cover 12. The cover 12 may comprise a single layer or multiple layers. The cover 12 layer(s) may comprise glass, one or more polymers (e.g., acrylic), polarizer(s), anti-reflective films, combinations thereof, or the like. In exemplary embodiments, without limitation, the frame 14 includes a ledge 13 around an inner perimeter thereof which receives a portion of a bottom surface of the cover 12. The cover 12 may be transparent or translucent over at least a majority of a surface area thereof, such as to allow viewing therethrough.

The cover subassembly 40 may comprise a number of clips 10. In this way, each of the clips 10A-10D may include a lip 11A-11D, by way of example. In exemplary embodiments, without limitation, one of the clips 10 is provided for each side of the door frame 14. For example, without limitation, the door frame 14 may be generally rectangular in shape with four clips 10A, 10B, 10C, and 10D provided for the top, bottom, left side, and right side thereof. In this way, a perimeter of the door frame 14 may be surrounded by the clips 10.

Some, preferably (but optionally) all, of the clips 10 may extend along a side of the door frame 14 and may comprise a lip 11. The lips 11 may extend over a portion of a front surface of the cover 12. In this way, the cover 12 may be secured from forward movement. The cover 12 may be secured from rearward movement by the ledge 13 of the door frame 14. In this way, a portion of the cover 12 may be sandwiched between the ledge 13 and the lip 11. Optionally, adhesive may be provided at the forward and/or rearward surface of the cover 12 to additionally secure it to the lip 11 and/or ledge 13.

Some, preferably (but optionally) all, of the clips 10 may comprise a stud 20. The stud 20 may serve to strengthen the clips 10. The stud 20 may comprise a planar or substantially (e.g., within 90%) planar object. The stud 20 may extend along an interior facing portion of a fascia 21 of the clips 10. Preferably, the studs 20 each extend over at least a majority of the interior surface of the fascia 21, though such is not required. Each of the clips 10A-10D may include a fascia 21A-21D in exemplary embodiment.

The fascia 21, for example without limitation, may be painted, textured, or the like. The studs 20 may be adhered, welded, bonded, or otherwise permanently attached to an interior surface of the fascia 21 though such is not required. Alternatively, the studs 20 may be integrally formed with the fascia 21. Alternatively still, the studs 20 may be secured to the fascia 21 by fasteners and/or nuts 22.

A space may be provided between at least portions of the stud 20 and the fascia 21, such as to accommodate a least a portion of the fasteners. The fasteners may comprise threaded shafts, such as in the form of bolts, by way of non-limiting example.

The studs 20 may comprise apertures, such as for receiving the fasteners. For example, without limitation, the apertures in the studs 20 may be threaded to receive the threaded shafts of the fasteners. The apertures may be aligned with apertures in the door frame 14.

As another example, without limitation, the fasteners may be integrally formed with or permanently attached to the studs 20 and/or fascia 21. In such embodiments, the fasteners may be aligned with the apertures in the door frame 14.

In exemplary embodiments, without limitation, the fasteners may be extended from between the fascia 21 and studs 20 through the aperture therein and through the aperture in the door frame 14 and may be secured by a nut 22. In this way, the clips 10 may be secured to the door frame 14. In other exemplary embodiments, without limitation, the fasteners may be extended through the aperture in the door frame 14 and may be secured by a nut 22, thereby securing the clips 10 to the door frame 14.

Multiple apertures, fasteners, and/or nuts 22 may be provided for each of the clips 10.

Some of the clips 10 may comprise exterior vents 18. The exterior vents 18 may be aligned with interior vents 16 in the door frame 14, such as to allow airflow into the display assemblies 60. In exemplary embodiments, without limitation, such exterior vents 18 are provided at top and bottom clips 10B, 10D, such as to align with top and bottom interior vents 16 in the door frame 14. Other location and/or number of vents 16, 18 may be utilized. The vents 16, 18 may be part of and/or provide access to one or more airflow pathways of the display assembly 60.

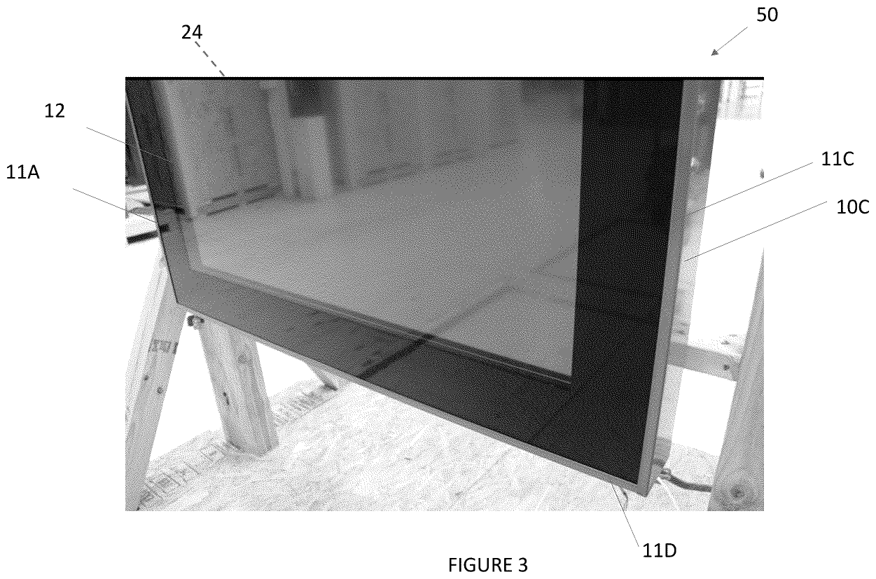

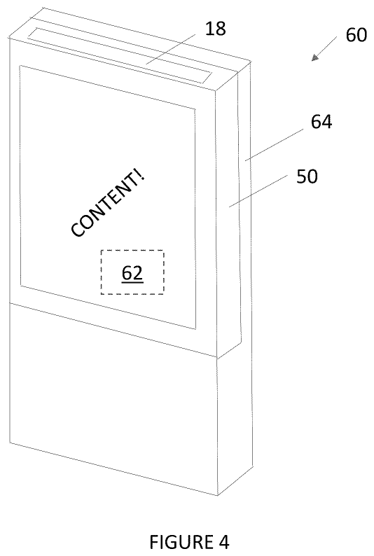

As illustrated with particular regard to FIG. 3 and FIG. 4, the cover subassembly 40 may be part of a display subassembly 50, which may include at least one electronic display 24. The electronic display 24 may be located rearwards, and optionally (but preferably) spaced apart from, the cover 12. The electronic display 24 may comprise a liquid crystal type display, though other types of displays may be utilized, such as but not limited to, organic light emitting diode, light emitting diode, plasma, combinations thereof, or the like. The electronic display 24 may optionally be touch sensitive.

The electronic display 24 in exemplary embodiments, without limitation, may comprise a liquid crystal layer and a backlight (preferably direct, but optionally edge lit). The electronic display 24 may include more polarizers, anti-reflective films, optical layers or coatings, combinations thereof, or the like.

The display assemblies 60 may include one or more open airflow pathways. The open airflow pathways may be open to an ambient environment, such as by way of the vents 16, 18. Alternatively, or additionally, the display assemblies 60 may comprise one or more closed airflow pathways. The closed airflow pathways may be separated from the ambient environment and/or the open airflow pathways. The closed airflow pathway(s) may each comprise one or more spaces, channels, combinations thereof, or the like within the display assemblies 60.

The closed airflow pathway(s) may be separated from ambient and/or the open airflow pathway(s), such as in accordance with at least ingress protection (IP) code 55 or higher available from the International Electrotechnical Commission of Geneva Switzerland. E.g., https://www.iec.ch/ip-ratings. More preferably, but optionally, such separation may be in accordance with at least IP 65 or higher.

The open and closed airflow pathway(s) may extend adjacent to one another to transfer heat. In exemplary embodiments, without limitation, heat exchangers or the like may be provided to enhance such transfer while maintaining the aforementioned separation.

The display assemblies 60 may comprise one or more internal components 62. The internal components 62 may include one or more of: fans, video players, sensors (e.g., temperature, pressure, humidity, location/GPS, light (e.g., ambient light, display 24 illumination), combinations thereof, or the like), controllers for the same, network connectivity device (e.g., routers, modems, antenna, combinations thereof, or the like), VOIP equipment, emergency calling equipment, heat exchangers, thermal devices (e.g., thermoelectric coolers, air conditioners, heaters), electrical equipment (e.g., batteries, power supplies, transformers, circuit breakers, combinations thereof, or the like), cameras, lights, microphones, combinations thereof, or the like. The internal components 62 may support operation of the display assembly 60 and/or display subassemblies 50. The illustrated location, number, size, shape, and/or the like of the internal components 62 is not intended to be limiting. The internal components 62 may be part of the display subassembly 50 and/or the unit 60.

A single one of, or multiple, of the display subassemblies 50 may be provided at a given display assembly 60. For example, without limitation, two of the display subassemblies 50 may be provided in a back-to-back type arrangement at the display assembly 60. The display assembly 60 may comprise a structural framework 64 (e.g., one or more members) arranged to support the display subassemblies 50. The display subassemblies 50 may be movably connected to the structural framework 64, such as, but not limited to, in a hinged arrangement. The structural framework 64 may be configured for mounting at or to a ground surface (e.g., a city sidewalk), a vehicle, an item of street furniture (e.g., bus shelter, phone booth, utility box, utility pole, newspaper stand, poster display, former and/or retrofitted versions thereof, combinations thereof, or the like), a wall, combinations thereof, or the like.

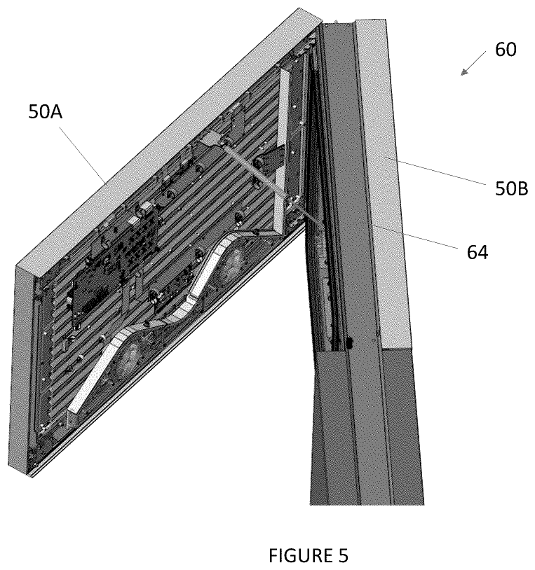

FIG. 5 illustrates the display assembly 60 with the display subassembly 50 moved into an open position, such as where a bottom and/or bottom portion of the display subassembly 50 is moved away from the structural framework 64. As illustrated, the display assembly 60 may include multiple display subassemblies 50A, 50B, such as attached to opposing sides of the structural framework 64.

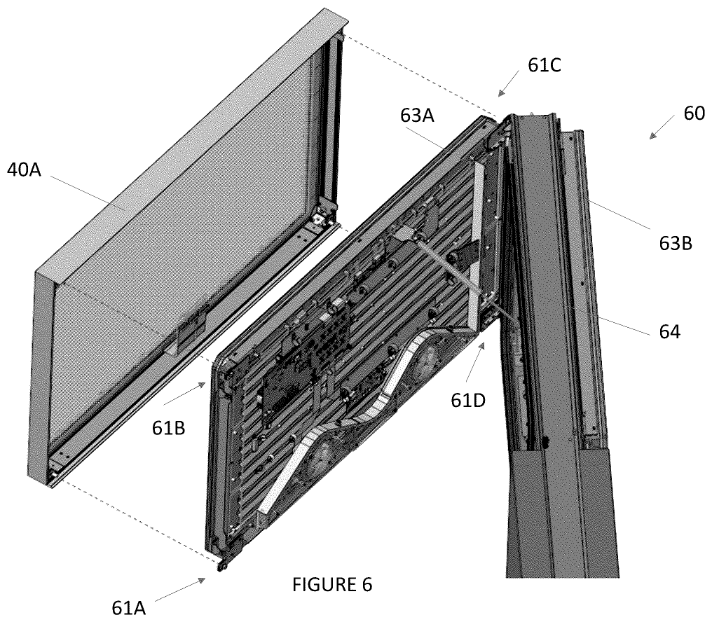

FIG. 6 illustrates the display assembly 60 with the cover subassemblies 40 removed. The second cover subassembly 40B is not illustrated, while the first cover subassembly 40A is illustrated in an exploded view. A remainder 63A, 63B of the display subassemblies 50A, 50B may remain attached to the structural framework 64. The remainder 63 of the display subassembly 50 may comprise a frame, one or more members, one or more panels, the electronic display 24, some or all of the internal components 62, combinations thereof, or the like.

The display subassemblies 50 may be connected to the structural framework 64 by way of one or more hinges, members, gas struts, combinations thereof, or the like to facilitate movement between an opened position (away, at least in part, from the structural framework 64) and a closed position (against the structural framework 64).

In exemplary embodiments, without limitation, the cover subassemblies 40 may be removed by removing associated fasteners, such as four nuts and/or threaded fasteners (e.g., bolts) generally indicated at items 61A, 61B, 61C, and 61D.

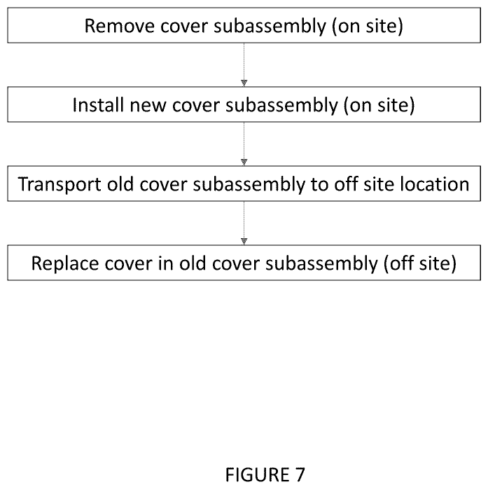

FIG. 7 provides an exemplary method of replacing one of the cover subassemblies 40 at a given display assembly 60. If a cover subassembly 40 needs replaced, such as due to vandalism and/or environmental damage by way of non-limiting example, a technician or crew may be dispatched to a location where the display assembly 60 is installed. The cover subassembly 40 may be removed. The cover subassembly 40 may be attached at one or more hinge points, such as by way of one or more pins, bolts, nuts, and/or other fasteners in exemplary embodiments without limitation.

In other exemplary embodiments, without limitation, the display subassembly 50 may be moved away from the structural framework 64 to access the nuts 22 and/or fasteners. The nuts 22 and/or fasteners may be removed so the clips 10 and cover 12 may be removed from, or with, the door frame 14.

A new cover subassembly 40 may be installed, such as by installing a new cover 12 and clips 10, and optionally door frame 14, including threading the nuts 22 (same or new) to the fasteners thereof, or vice-versa. The display subassembly 50 may be closed. The damaged/removed cover subassembly 40 may be transported off site, where a new cover 12 may be installed.

In this way, a user (e.g., customer, service provider) may purchase or otherwise be provided with an extra cover subassembly 40 (e.g., door frame 14 and/or clips 10) and one or more extra covers 12 and easily and efficiently replace any damaged covers 12. The damaged/removed cover subassembly 40 may be reconditioned off site (e.g., new cover 12 installed) so that the damaged/removed cover subassembly 40 is ready for reuse. This may limit time on site and need to replace an entire display subassembly 50, by way of non-limiting example.

A new set of nuts 22 and/or fasteners may be used with installation at a display assembly 60, and/or some of all of the nuts 22 and/or fasteners may be kept and reused at the display assembly 60.

While nuts 22 and threaded fasteners are sometimes shown and/or discussed, other types of fastening arrangements and components may be utilized, such as but not necessarily limited to, pins, bolts, mating protrusions and recesses, friction fits, combinations thereof, or the like.

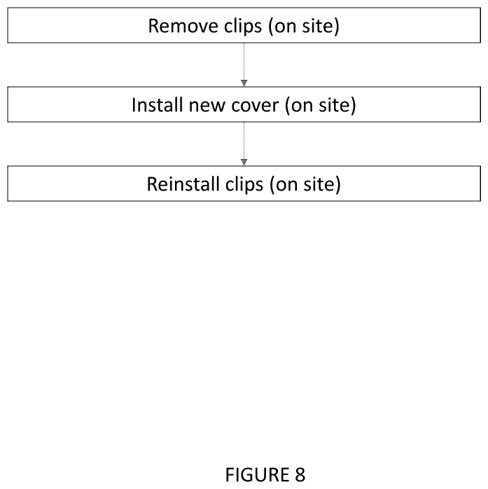

In other exemplary embodiments, such as illustrated with particular regard to FIG. 8 by way of non-limiting example, the cover subassembly 40 may be reused onsite, without the exception of the cover 12. For example, without limitation, the clips 10 may be removed onsite and a new cover 12 installed with the new clips 10.

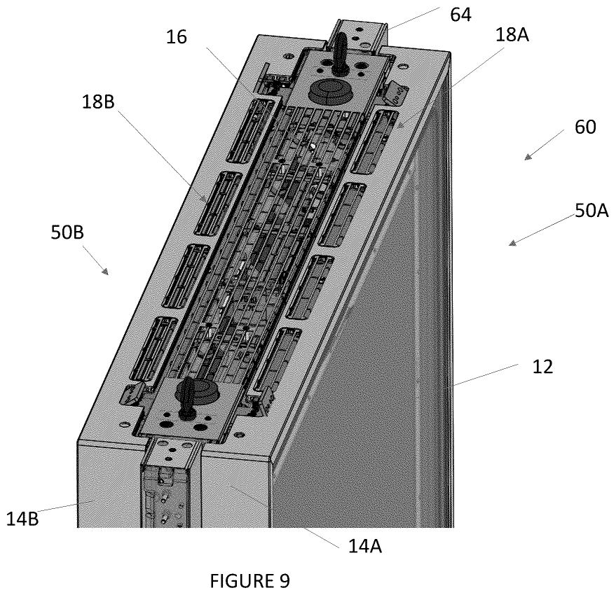

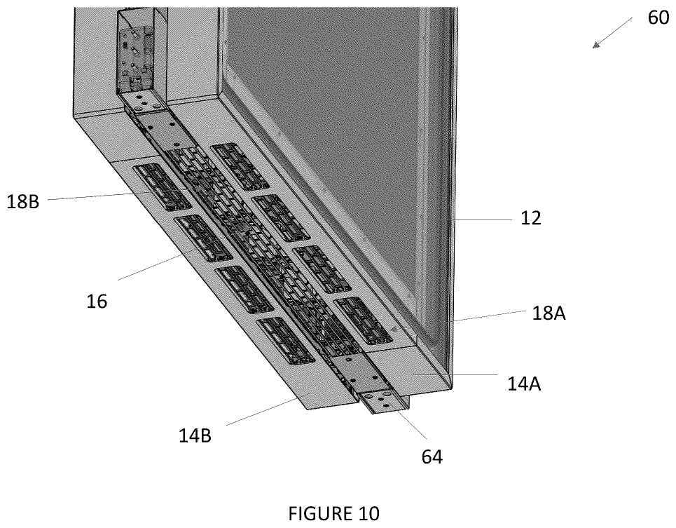

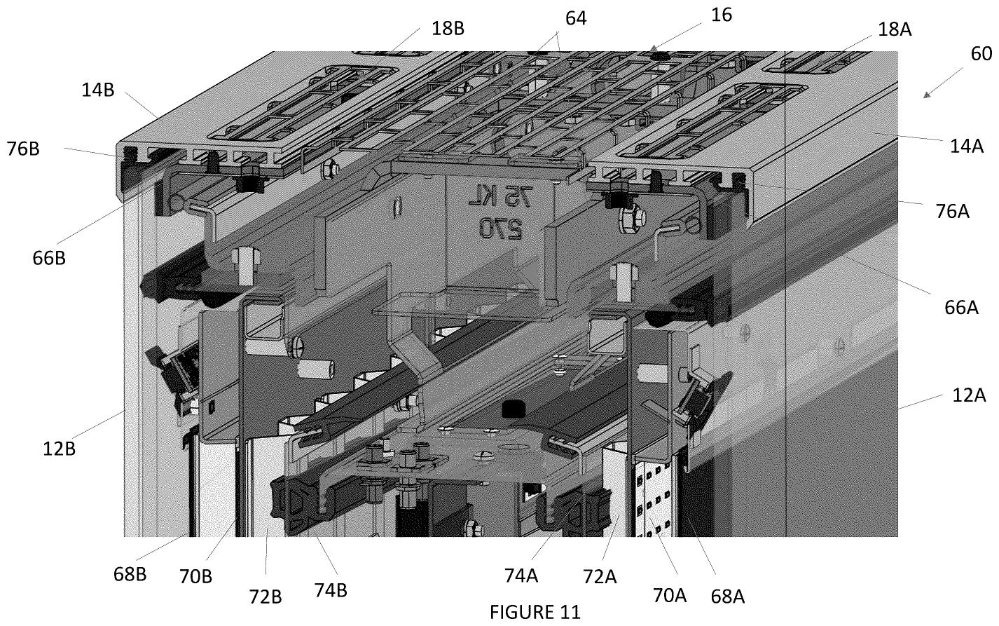

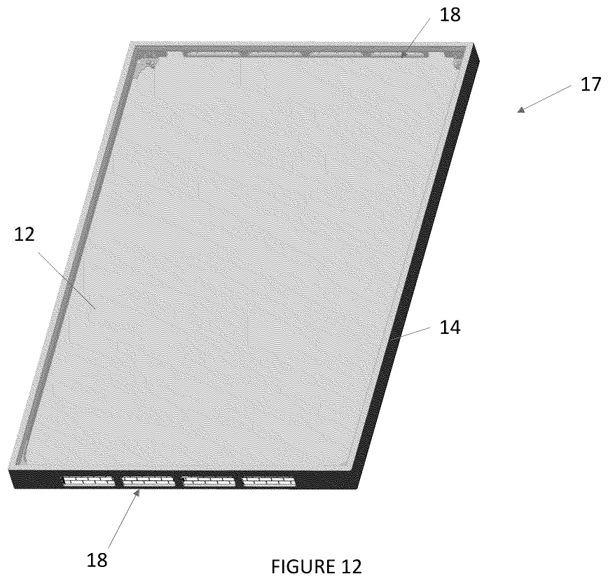

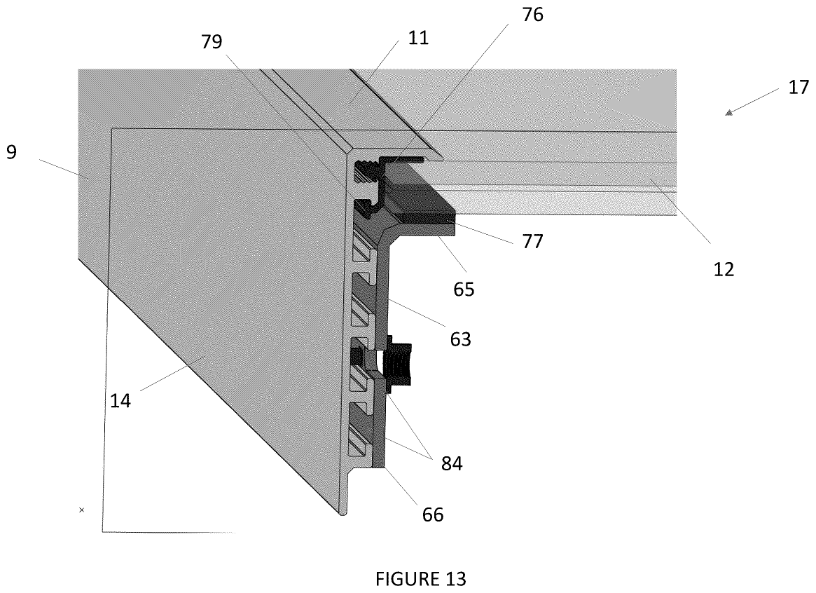

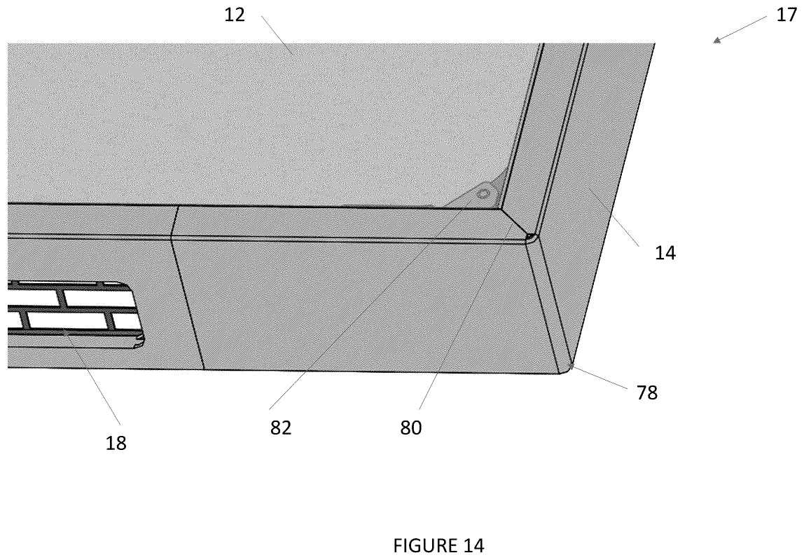

FIG. 9 through FIG. 14 illustrate another exemplary embodiment of the unit 60 and/or display assemblies 50 and/or door frame 14. The same or similar components as other embodiments provided herein, including those of any one or more of FIGS. 1-8, may be numbered correspondingly to the numbering used for FIGS. 1-8.

The door frame 14 may be formed in accordance with, and/or have some or all of the components, qualities, features, and/or characteristics, some or all of the disclosures of WO2025/072596 published Apr. 3, 2025 (the “596 Pub.”), the disclosures of the '596 Pub. being hereby incorporated by reference in their entirety as if fully restated herein.

The door frame 14 may include a body 9 and a lip 11 extending therefrom. In exemplary embodiments, the body 9 is at least substantially planar. The lip 11 may extend at least substantially perpendicular from the body 9 at an end thereof, such as with rounded section therebetween.

An interior component 66 may be provided, which may include a body 63 and a lip 65 extending therefrom. In exemplary embodiments, the body 63 is at least substantially planar. The lip 65 may extend at least substantially perpendicular from the body 63 at an end thereof, such as with a rounded section therebetween.

The interior component 66, and particularly the body 63 and lip 65 thereof, may at least substantially align with a door frame 14, and particularly the body 9 and the lip 11 portion thereof, respectively, when installed. For example, the body 9 of the door frame 14 may extend at least substantially parallel with the body 63 of the interior component 66. The lip 11 of the door frame 14 may extend at least substantially parallel with the lip 65 of the interior component 66. In exemplary embodiments, the body 9 is at least substantially planar. The lip 11 may extend at least substantially perpendicular from the body 9 at an end thereof, such as with rounding therebetween.

The interior component 66 may be connected to the door frame 14 via fasteners (e.g., nuts or bolts). The fasteners may be inserted through holes in the body 63 of the interior component 66, and may extend into channels 84 formed on an interior facing side of the body 9 of the door frame 14. For example, without limitation, heads of the fasteners may be secured within the channels 84 of the door frame 14 and threaded portions of the fasteners may be extended through holes in the body 63 of the interior component 66, and a nut may be tightened against the interior component 66 to secure the interior component 66 and the door frame 14 to one another. Welding, adhesives, or the like may alternatively or additionally be utilized.

An interior surface of the lip 11 of the door frame 14 may be sufficiently spaced from an outward facing surface of the lip 65 of the interior component 66 to accommodate the cover 12. The cover 12 may include multiple layers of a transparent or translucent layer joined by an optically clear adhesive. The cover 12 may include, or be connected to, one or more optical films or layers, such as polarizers. When installed, the lip 11 of the door frame 14 may extend over at least a portion of an outward facing surface of the cover 12. In this way, when installed, the cover 12 may be effectively sandwiched between the lip 11 of the door frame 14 and the lip 65 of the interior component 66, thereby providing frictional engagement (direct or indirect) which secures the cover 12 and/or providing compressive forces to the cover 12. Frictional engagement and/or securement forces may also be provided at side walls of the cover 12, such as by way of the body 9 of the door frame 14. As the door frame 14 preferably extends about an outer perimeter of the cover 12, these forces described herein may be well distributed and the cover 12 well secured.

The interior component 66 and the door frame 14 may each be provided over all, or at least substantially all, of a perimeter of the cover 12. However, in other exemplary embodiments, the door frame may be provided over all, or at least substantially all, of a perimeter of the cover 12 and a plurality of discrete interior components 66 are provided at spaced intervals about the door frame 14.

In exemplary embodiment, without limitation, a material 77 is interposed between the interior surface of the cover 12 and the outward facing surface of the lip 65 of the interior component 66. The material 77 may assist with sealing, reduce fiction, provide adhesion, combinations thereof, or the like. The material 77 preferably comprises one or more rubbers or silicones, though other types and kinds of material may be utilized. The material 77 may be provided about some or all of a perimeter of the interior facing surface of the cover 12 and/or exterior facing surface of the lip 65 of the interior component 66. The material 77 need not necessarily be provided at an extract outer edge of the cover 12, but may be positioned along and adjacent to the same.

A gasket 76 may be provided. In exemplary embodiments, the gasket 76 extends to at least one of the channels 84 of the door frame 14 and between the interior facing surface of the lip 11 of the door frame 14 and the outward facing surface of the cover 12. The gasket 76 may assist with sealing, reduce fiction, provide adhesion, combinations thereof, or the like. The gasket 76 preferably comprises one or more rubbers or silicones, though other types and kinds of material may be utilized. The gasket 76 may be a same or different type of material from the material 77. The gasket 76 may be provided about some or all of a perimeter of the exterior facing surface of the cover 12 and/or interior facing surface of the lip 11 of the door frame 14.

The gasket 76 preferably comprises one or more end portions 79 which engage portions of the door frame 14, and preferably those portions forming at least one of the channels 84.

Preferably, a portion of the gasket 76 extends along outer side surfaces of the cover 12 and between the same and interior facing surface of the body 9 of the door frame 14. This may further assist with sealing and/or securement.

Securing the interior component 66 to the door frame 14 with the cover 12 installed may secure the cover 12 in place. The cover 12 and door frame 14 may define, or be part of, a door frame subassembly 17. The door frame subassembly 17 may further comprise, and/or be defined by, the material 77 and/or the gasket 76. The door frame subassembly 17 may further comprise, and/or be defined by, the interior component 66.

The door frame subassembly 17 may be removed from the display assembly 50 and/or the unit 60, such as to replace a broken or damaged cover 12, such as discussed herein. Replacement may be performed in accordance with some or all of the steps shown and/or described herein, including but not necessarily limited to those of FIG. 7, and with regard to FIG. 8 but with the interior components 66 instead of the clips 10. In exemplary embodiments, without limitation, the door frame subassembly 17 is removed and replaced with another door frame subassembly 17, and the removed door frame subassembly 17 is repaired offsite (e.g., by replacing the damaged cover 12), thereby minimizing on site impact and preserving unit 60 uptime. In other exemplary embodiments, the door frame subassembly 17 is repaired onsite (e.g., by replacing the damaged cover 12). In any event, replacing the cover 12 may include removing the door frame subassembly 17 or moving the door frame subassembly 17 so as to allow access to the fasteners holding the interior component(s) 66 to the door frame 14, and replacing the cover 12. This may allow for more efficient repair and replacement.

Vents 18 may be provided in portions of the door frame 14, such as at portions corresponding to upper and lower portions of the door frame 14 when installed. The vents 18 may be provided at the body 9 of the door frame 14. Each of the vents 18 may comprise one or more openings. Some or all such openings may include a grid of various pattern, such as to prevent casual access. The door frame 14 may be formed in accordance with the '596 Pub. and the vents 18 may be cut out of the door frame 14 after extrusion, such as by CNC machining, laser cutting, water jet, combinations thereof, or the like. A vent 18 may be provided for each door frame 14 and/or door frame subassembly 17, which may correspond to each display assembly 50 of a unit 60. For example, where the unit 60 includes two display assemblies 50, two vents 18A, 18B may be provided. However, the unit 60 may include a single display assembly 50 and vent 18, or a single display assembly 50 and a second door subassembly 17 with another vent 18 with or without a second electronic display. For example, the second door subassembly 17 may instead be used as an access door, a blank panel, a static poster holder, or the like. These are just some examples provided without limitation.

The vent(s) 18 may be in addition to a vent 16 formed in the structural framework 64 to which the one or more display assemblies 50 are connected. Incorporation of the vents 18 in the door frame 14, especially with the optional, but preferably, vent 16 in the structural framework 64, may allow for a larger overall area for airflow ingestion and exhaustion when installed as part of a unit 60 and/or display assembly 50 thereof. This may allow for more efficient airflow and/or thermal management, such as by reducing backpressure, reducing air velocity (allowing longer dwell times for thermal transfer), and/or reducing noise. Preferably, the vents 18 in the door frame 14 are aligned with the vents 16 in the structural framework 64, though other arrangements may be utilized.

The lip 11 of the door frame assembly 14 may aid with securing the cover 12, such as from popping out due to internal pressure forces generated during use and/or ambient condition exposure. For example, without limitation, solar heating of air behind the cover and/or airflow changes to such air can cause significant pressure increases against the cover 12, which, particularly when repeated over the years, can tend to lead to undesirable conditions (e.g., leaking, breakage).

The body 63 of the interior component 66 is, in exemplary embodiments, provided interior to some or all of an area of the vents 16 of the door frame 14, thereby acting as an umbrella. This arrangement may prevent moisture, such as from ambient rain, from travelling further into the unit 60, thereby reducing moisture exposure to sensitive electronics within the units 60, such as by preventing direct contact and leakage through capillary action or otherwise.

In exemplary embodiments, joined edges 80 of corners 78 of the door frame 14 are laser welded. Other portions of the door frame subassembly 14 may be laser welded, such as where the door frame 14 is joined to itself.

The corners 78 of the door frame 14 may be reinforced by brackets 82, such as extending between body 9 portions and/or lip 11 portions of the same. The brackets 82 may extend at an angle between the various sides of the door frame, such as at an angle of least substantially 45 degrees relative to the underlying portions of the door frame 14.

The corners 78 of the door frame 14 may be rounded, such as by way of the teachings provided in the '596 Pub.

Each of the display assemblies 50A, 50B may comprise, in exemplary embodiments, one of the door frames 14A, 14B and one of the covers 12A, 12B installed thereto. Each of the display assemblies 50A, 50B may include an electronic display layer 68A, 68B (e.g., liquid crystal layer) located interior to and spaced apart from, the cover 12A, 12B, though direct optical bonding may be used in other embodiments. Each of the display assemblies 50A, 50B may include an illumination device 70A, 70B located behind, and spaced apart from, the electronic display layer 68A, 68B. The illumination devices 70 may include light emitting diodes (LEDs) provided at a substrate, such as in a direct backlighting arrangement. However, in other embodiments, edge lighting may be utilized. In yet other exemplary embodiments, the electronic display layer 68A, 68B may be an emissive display and may comprise organic light emitting diodes (OLEDs) or LEDs (e.g., direct LED type display). Each of the display assemblies 50A, 50B may include a rear panel 74A, 74B which may be provided behind, and spaced apart from, the illumination device 70, where utilized. Where the illumination device 70 is not utilized, the rear panel 74 may be located rearward of, and spaced apart from, the electronic display layer 68, such as without the illumination device 70 therebetween. Corrugation 72A, 72B or other material or dividers (e.g., not necessarily in a corrugated pattern) may be located within, and preferably extend between, the illumination device 70 and the rear panel 74, or between the electronic display layer 68 and the rear panel 74, such as in the case where emissive type displays are utilized.

A space between the cover 12 and the electronic display layer 68 may form part of a closed airflow pathway in the unit 60 and/or display assembly 50 thereof, which may also extend behind the rear panel 74. A space between the illumination device 70 (or electronic display layer 68 in the case of an emissive display) and the rear panel 74 may form part of an open airflow pathway in the unit 60 and/or display assembly 50 thereof. The open airflow pathway may be fluidly connected to some or all of the vents 16, 18. Separate ones of the open airflow pathway may optionally be provided for each display assembly 50 of a unit 60 such that the vents 16, 18 may or may not be in direct fluid connection. Separation between the closed airflow pathway and the open airflow pathway(s) and/or ambient may be in accordance with IP55 or higher, more preferably, but optionally, in accordance with at least IP65 or higher (e.g., IP66, etc.).

While the units 60 are sometimes shown and/or described herein as double sided-such as with two display assemblies 50 installed to opposing sides of the structural framework 64—in other exemplary embodiments, a single display assembly 50 may be utilized, such as with blank cover, a poster holder, a door assembly, combinations thereof, or the like, installed at an opposing side thereof. In such embodiments, the poster holder, door assembly, or the like may include at least the door frame subassembly 17 or certain components thereof, such as the door frame 14 and cover 12, though the cover 12 may comprise sheet metal, ink (e.g., printed black) on one or more surfaces of the cover 12, frit glass, combinations thereof, or the like.

As used herein, the term substantially may refer to within 20% of unless otherwise indicated.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention.

Certain operations described herein may be performed by one or more electronic devices. Each electronic device may comprise one or more processors, electronic storage devices, executable software instructions, combinations thereof, and the like configured to perform the operations described herein. The features and/or functionality shown and/or described herein may be accomplished by way of stored, executable software instructions, such as in the form of applications, programs, routines, combinations thereof, or the like. The electronic devices may be general purpose computers or specialized computing devices. The electronic devices may comprise personal computers, smartphones, tablets, databases, servers, or the like. The electronic connections and transmissions described herein may be accomplished by one or more wired or wireless connectivity components (e.g., routers, modems, ethernet cables, fiber optic cable, telephone cables, signal repeaters, and the like) and/or networks (e.g., internets, intranets, cellular networks, the world wide web, local area networks, and the like). The computerized hardware, software, components, systems, steps, methods, and/or processes described herein may serve to improve the speed of the computerized hardware, software, systems, steps, methods, and/or processes described herein. The electronic devices, including but not necessarily limited to the electronic storage devices, databases, controllers, or the like, may comprise and/or be configured to hold, solely non-transitory signals.

What is claimed is:

1. A door frame with integrated ventilation for a display assembly of a display unit,
said door frame comprising:
a body, said body being at least substantially planar; and
at least one vent provided at the body.

2. The door frame of claim 1 further comprising:
a lip extending at least substantially perpendicular to the body and from an end thereof.

3. The door frame of claim 2 wherein:
the at least one vent comprises a first vent provided at a first portion of the body corresponding to an upper portion of the door frame when installed and a second vent provided at a second portion of the body corresponding to a lower portion of the door frame when installed.

4. The door frame of claim 3 wherein:
the door frame is unitary and formed into a rectangle.

5. The door frame of claim 4 formed by a process comprising:
extruding metal shaped into the body and the lip;
cutting the first and second vents into the first and second portions of the body; and
bending the metal to form the rectangle.

6. A door frame subassembly comprising:
the door frame of claim 4;
a cover installed at the lip; and
an interior component located interior to the door frame, said interior component comprising a body, said body being at least substantially planar, and a lip extending at least substantially perpendicular to the body and from an end thereof.

7. The door frame subassembly of claim 6 wherein:
the lip of the interior component extends beneath the first vent and the second vent.

8. The door frame subassembly of claim 7 further comprising:
apertures in the body of the interior component;
channels formed in an interior facing surface of the body of the door frame; and
fasteners securing the interior component to the door frame, said fasteners extending from the channels and through the aperture in the body.

9. The door frame subassembly of claim 8 further comprising:
a gasket secured to one of the channels and having a portion interposed between an exterior facing surface of the cover and interior facing surface of the lip of the door frame.

10. The door frame subassembly of claim 9 further comprising:
a material interposed between an interior facing surface of the cover and an exterior facing surface of the lip of the interior component.

11. The door frame subassembly of claim 10 wherein:
the gasket and the material comprise at least one of: rubber and silicone.

12. The door frame subassembly of claim 8 wherein:
the interior component is unitary and formed into the rectangle.

13. The door frame subassembly of claim 6 wherein:
the cover comprises multiple layers of a translucent or transparent material connected by an optically clear adhesive.

14. A display subassembly with integrated door frame ventilation, said display
assembly comprising:
the door frame subassembly of claim 6; and
an electronic display layer located interior to, and spaced apart from, the cover.

15. The display subassembly of claim 14 wherein:
the electronic display layer comprises liquid crystals, and the display subassembly further comprises an illumination device located interior to, and spaced apart from, the electronic display layer, said illumination device comprising light emitting diodes arranged to directly illuminate the electronic display layer when activated; or
the electronic display layer comprises organic light emitting diodes.

16. A display unit with integrated door frame ventilation, said display unit comprising:
a structural framework; and
the display subassembly of claim 14 connected to the structural framework.

17. The display unit of claim 16 further comprising:
a vent located at the structural framework.

18. The display unit of claim 17 further comprising:
a closed airflow pathway extending within the display unit, including between the cover and the electronic display layer; and
an open airflow pathway extending within the display subassembly and between the vent of the structural framework, the first vent of the door frame and the second vent of the door frame.

19. A system for replacing covers of display units, said system comprising:
a plurality of the display units of claim 16; and
a plurality of spare ones of the door frame subassembly, wherein the spare ones of the door frame subassembly are installable to any of the display units in an interchangeable fashion.

20. A method for replacing damaged covers at display assemblies of display units,
said method comprising:
providing the display units, each comprising:
a structural framework;
a door frame subassembly with integrated ventilation, said door frame subassembly comprising:
a door frame which is unitary and formed into a rectangle, said door frame comprising:
a body, said body being at least substantially planar;
a lip extending at least substantially perpendicular to the body and from an end thereof; and
a first vent provided at a first portion of the body corresponding to an upper portion of the door frame when installed and a second vent provided at a second portion of the body corresponding to a lower portion of the door frame when installed;
a cover installed at the lip;
an interior component located interior to the door frame, said interior component comprising:
a body which is at least substantially planar;
a lip extending at least substantially perpendicular to the body and from an end thereof, wherein the lip of the interior component extends beneath the first vent and the second vent;
apertures in the body of the interior component; and
channels formed in an interior facing surface of the body of the door frame;
fasteners securing the interior component to the door frame, said fasteners extending from the channels and through the aperture in the body;
a material interposed between an interior facing surface of the cover and an exterior facing surface of the lip of the interior component; and
a gasket secured to one of the channels and having a portion interposed between an exterior facing surface of the cover and interior facing surface of the lip of the door frame; and
an electronic display layer located interior to, and spaced apart from, the cover;
providing one or more spare ones of the door frame subassembly;
removing a damaged one of the door frame subassemblies of a one of the display units;
replacing the damaged one of the door frame subassemblies of the one of the display units with one of the one or more spare ones of the door frame subassembly;
transporting the damaged one of the door frame subassemblies to an offsite location; and
repairing the damaged one of the door frame subassemblies at the offsite location.
